(19) United States
(12) Patent Application Publication
(10) Pub. No.: US 2001/0033589 A1
(43) Pub. Date: Oct. 25, 2001

(54) Solid state short wavelength laser and process

(76) Inventor: Jacques Isaac Pankove, Boulder, CO (US)

Correspondence Address: Earl C. Hancock, HOLLAND & HART LLP, P.O. Box 8749, Denver, CO, 80201, US

(21) Appl. No.: 09/780,300

(22) Filed: Feb. 9, 2001

Related U.S. Application Data
(60) Provisional application No. 60/181,474, filed on Feb. 10, 2000.

(51) Int. Cl. H01S 5/00

(52) U.S. Cl. 372/43

(57) ABSTRACT

A semiconductor laser includes a housing having a vacuum therein and a window that provides for the exit of a laser beam from the housing. A cathode within the housing emits a stream of electrons, and a wide bandgap semiconductor anode within said housing is impacted by the electron stream. The wide bandgap semiconductor has a bandgap energy and provides a resonator cavity that is physically spaced from the cathode. This resonant cavity is generally aligned with the window. An electric field acts in a space between the semiconductor anode and the cathode to accelerate the electron stream toward said semiconductor anode, thereby causing electron-hole pairs to be generated within the semiconductor anode, such that recombination of these electron-hole pairs generates photons having an energy that is generally equal to the bandgap energy of the semiconductor anode, these photons then forming a coherent laser beam.

### BACKGROUND OF THE INVENTION

1. Field of the Invention

This invention relates to the field of lasers, and more specifically to lasers wherein electron-hole pairs are generated within a Wide Bandgap (WBG) semiconductor member, and wherein recombination of these electron-hole pairs causes photons to be emitted from the WBG semiconductor member, these photons having generally an energy close to the bandgap energy of the WBG semiconductor member.

2. Description of the Related Art

It is known that electron-beam excitation of semiconductors has been provided in scanning electron microscopes, and while semiconductor lasers are also known, the need remains in the art for electron-beam pumped WBG semiconductor lasers (WBG solid state lasers) that provide a relatively short wavelength coherent-beam output.

In accordance with the present invention, a WBG semiconductor is subjected to the impact of an electron stream. As a result of this electron stream electron-hole pairs are created within the WBG semiconductor, recombination of these electron-holes pairs then generates photons in a resonant cavity and forms a coherent-output laser beam.

### BRIEF DESCRIPTION OF THE DRAWING

FIG. 1 is an overall view of a laser having a semiconductor anode element and a semiconductor cathode element in accordance with the present invention.

FIG. 2 is an enlarged section view of the anode element of FIG. 1 taken along the line 2-2 of FIG. 1.

FIG. 3 is an overall view of another laser in accordance with the present invention.

### DESCRIPTION OF THE PREFERRED EMBODIMENT

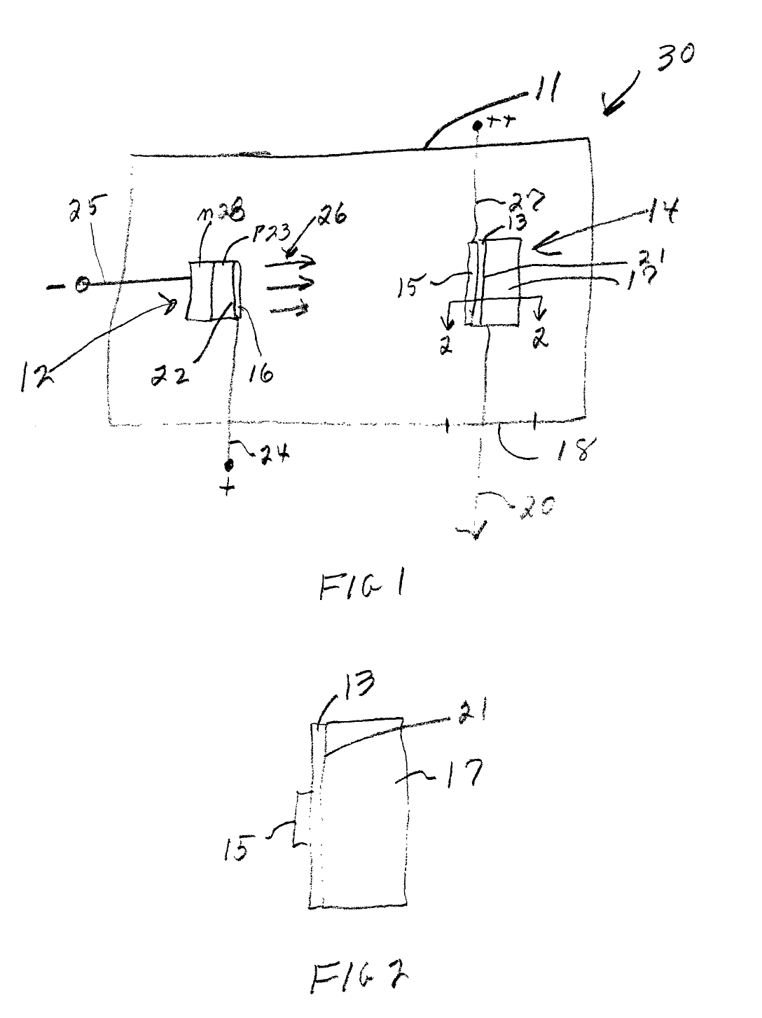

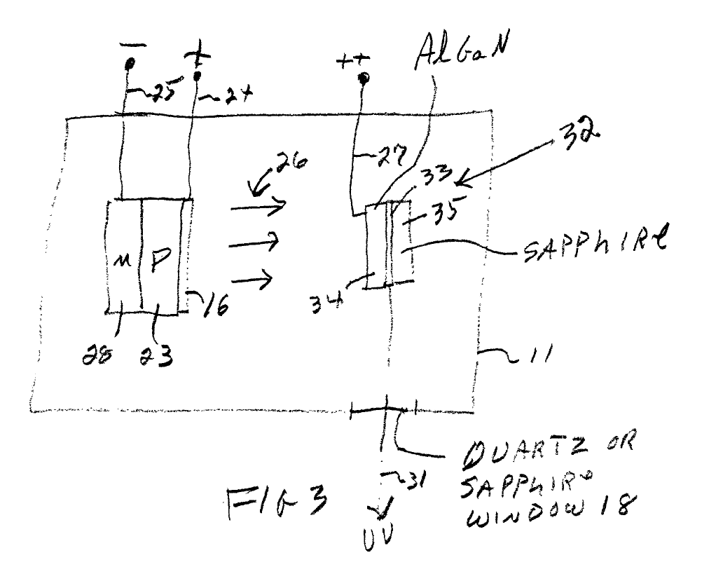

With reference to FIGS. 1 and 2, FIG. 1 is an overall view of a laser 10 in accordance with the invention, while FIG. 2 is an enlarged section view of laser 10's anode element 14 taken along line 2-2 shown in FIG. 1.

Laser 10 includes a source of electrons in the form of a semiconductor (GaN) cathode 12, and an anode 14 that includes a WBG semiconductor (GaN).

Laser 10 is positioned within an evacuated container or envelope 11 having a window 18 that is generally transparent to the laser output beam 20. That is, laser 10 operates in a vacuum environment.

The electrons 26 that originate at cathode 12 are accelerate toward anode 14 by the operation of an electric field that is created by a highly DC-biased thin and narrow metal stripe 15 that is located on a thin dielectric film or spacer 13, both of which are located on a surface 21 of anode 14 that faces cathode 12. Conductor 27 connects thin metal strip 15 to a relatively high magnitude source of DC voltage. Dielectric film 13 can be a substrate of layer of SiO₂ or AlO₂.

Thin dielectric spacer 13 electrically and mechanically separates and isolates metal stripe 15 from the adjacent surface 21 of WBG semiconductor member 17. Electrons 26 arriving at anode assembly 13-15, from cathode 12, penetrate thin metal stripe 15 and dielectric film 13, whereupon the electrons enter WBG semiconductor member 17 and thereby generate many electron-hole pairs within WBG semiconductor member 17.

When these electron hole pairs within WBG semiconductor member 17 recombine radiatively, photons are emitted having nearly the bandgap energy of semiconductor member 17 These emitted photons propagate along a line of population inversion (gain guided), and then emerge at an edge or side of WBG semiconductor 17.

Photon coherence is produced either by photon propagation inside a Fabry-Perot cavity that exists between opposite edges or sides of WBG semiconductor 17, or by photon propagation along a grating that is etched in a surface of WBG semiconductor 17, this grating providing a Bragg distributed feedback to the photon stream.

A preferred electron source or cathode 12 is a GaN pn-junction 12 wherein the surface 22 of a p-type GaN member 23 is coated with a low work function element 16, such as cesium or barium. Coating 16 provides negative electron affinity (NEA) to p-type GaN member 23. Electrons appearing in the conduction band of p-type GaN member 23 escape as electron stream 26, into the vacuum that is within evacuated envelope 11.

A forward DC bias is provided to pn-junction 12 by way of positive DC conductor 24 and negative DC conductor 25. This forward DC bias causes electrons to be injected from an n-type GaN electron-reservoir 28, and into the conduction band of the p-type GaN 23. In this way, the emitted electron current 26 is controlled by the DC bias 24, 25 that exists across GaN pn-junction 12.

Anode 14 consists of a WBG semiconductor, preferably a WBG semiconductor having a direct bandgap, such as GaN or AlN, or an alloy of these two nitrides. Other usable WBG semiconductors include ZnO and MgO.

GaN (Eg=3.4 eV) emits efficiently 365 nm photons, AlN (Eg=6.2 eV) emits 200 nm photons; ZnO (Eg=3.3 eV) emits 370 nm photons; and MgO (Eg=7.6 eV) emits 160 nm photons.

The shortest wavelength photons propagate in the vacuum that is within envelope 11. Using an alloy of GaAlN as WBG semiconductor 17 permits a selection of wavelengths by choosing an appropriate composition of this alloy. Furthermore, the laser's photon wavelength can be tailored, as desired, by using a quantum well of InN in GaN or a quantum well of GaN in AlN.

Also, rare earth doped sapphire 17 provides a WBG semiconductor 17 that, when bombarded through thin metal stripe 15 and thin dielectric spacer 13, emits a variety of wavelengths. Lasing wavelength is then selected by a resonator, such as the above-mentioned Fabry-Perot cavity or the above-mentioned distributed feedback grating.

GaN cathode 12 and GaN anode 14 are physically spaced from each other, and face each other within evacuated envelope 11, with envelope 11 including a suitable window 18 for exit of laser beam 20.

FIG. 3 provides an embodiment of the invention wherein laser 30 provides an ultraviolet (UV) output beam 31. As with the embodiment of FIGS. 1 and 2, laser 30 includes a GaN cathode that includes a pn-junction that is formed by p-type GaN 23, n-type GaN, and NEA coating 16, to thereby generate an electron stream 26.

In the embodiment of FIG. 3, anode 32 comprises a narrow ribbon 33 of a WBG semiconductor that is sandwiched between two wider bandgap layers 34 and 35 that are respectively formed of AlGaN and sapphire, wherein layers 34 and 35 have a lower refractive index than does active region 33. Thus, layers 34 and 35 form a waveguide for the UV output 31, which waveguide, when textured, provides a resonant distributed feedback.

Electron affinity refers to the strength of adhesion of the electrons to the host body. Negative electron affinity means that the vacuum level of the semiconductor is below the conduction band edge of the semiconductor.

This invention has been described in detail while making reference to preferred embodiments thereof. However, since it is known that others skilled in the art will, upon learning of this invention, readily visualize yet other embodiments that are within the spirit and scope of this invention, this detailed description is not to be taken as a limitation on the spirit and scope of this invention.

What is claimed is:

1. A semiconductor laser, comprising:
a housing having a vacuum therein;
a window within said housing providing for exit of a laser beam from said housing;
a cathode within said housing for emitting a stream of electrons;
a wide bandgap semiconductor anode within said housing, said wide bandgap semiconductor having a bandgap energy, said semiconductor anode providing a resonator cavity, said semiconductor anode being spaced from said cathode, and said semiconductor anode being generally aligned with said window; and
an electric field acting in a space between said semiconductor anode and said cathode for accelerating said electron stream toward said semiconductor anode, to thereby cause electron-hole pairs to be generated within said semiconductor anode such that recombination of said electron-hole pairs operates to generate photons having a bandgap energy that is generally equal to said bandgap energy of said semiconductor anode, said photons comprising said laser beam.

2. The semiconductor laser of claim 1 wherein said wide bandgap semiconductor anode is selected from a group consisting of GaN, AlN, ZnO, MgO, and rare-earth-doped sapphire.

3. The semiconductor laser of claim 1 wherein said wide bandgap semiconductor is an alloy of GaAlN that is selected from the group a quantum well of InN in GaN, a quantum-well of GaN in AlN, and rare earth doped sapphire.

4. The semiconductor laser of claim 1 wherein said wide bandgap semiconductor anode includes a surface that faces said cathode, including:
a thin dielectric layer on said surface;
a thin metal layer on said dielectric layer; and
a source of positive DC voltage connected to said thin metal layer to thereby accelerate said electron stream toward said semiconductor anode.

5. The semiconductor laser of claim 1 wherein said cathode comprises:
a DC-biased pn GaN junction operable to generate said stream of electrons; and
a coating that provides negative electron affinity to said pn GaN junction located on a surface of said pn GaN junction that faces said wide bandgap semiconductor anode.

6. The semiconductor laser of claim 1 wherein said resonator cavity is selected from a group consisting of Fabry-Perot cavity and distributed feedback grating.

7. A semiconductor laser, comprising:
a housing having a vacuum therein;
a window within said housing providing for exit of a laser beam from said housing;
a DC-biased GaN pn-junction within said housing operable to generate a stream of electrons;
a wide bandgap semiconductor anode within said housing;
said semiconductor anode being selected from a group consisting of GaN, AlN, ZnO and MgO;
said semiconductor having a bandgap energy;
said semiconductor anode providing a resonant cavity;
said semiconductor anode being physically spaced from said cathode;
said semiconductor anode being generally aligned with said window;
said semiconductor anode including a surface that faces said cathode;
a thin dielectric layer on said anode surface;
a thin metal layer on said dielectric layer;
a source of positive DC voltage connected to said thin metal layer operable to accelerate said electron stream toward said anode surface;
said electron stream causing electron-hole pairs to be generated within said anode such that recombination of said electron-hole pairs operates to generate photons having an energy that is generally equal to said bandgap energy of said semiconductor anode, said photons forming said laser beam.

8. The semiconductor laser of claim 7 including:
a coating that provides negative electron affinity to the p-type surface of said GaN pn-junction, said p-type surface facing said anode.

9. The semiconductor laser of claim 7 wherein said semiconductor anode forms a Fabry-Perot cavity.

10. A UV emitting and electron pumped semiconductor laser, comprising:
a housing having a vacuum therein;
a window within said housing providing for passage of a UV laser beam from said housing;
a cathode within said housing for emitting a stream of electrons;
an anode within said housing, said anode having a thin layer of a wide bandgap semiconductor sandwiched between a first and a second bandgap layer that both have a lower refractive index than the refractive index of said thin layer of said wide bandgap semiconductor, to thereby provide a wave guide for UV radiation;
said anode being spaced from said cathode;
said anode being generally aligned with said window; and
an electric field acting in a space between said semiconductor anode and said cathode for accelerating said electron stream toward said anode, to thereby cause electron-hole pairs to be generated within said thin layer of said wide bandgap semiconductor, recombination of said electron-hole pairs operating to generate photons having an energy that is generally equal to said bandgap energy of said thin layer of said wide bandgap semiconductor, said photons comprising said UV laser beam.

11. The semiconductor laser of claim 10 wherein said this layer of said wide bandgap semiconductor is selected from a group consisting of GaN, AlN, ZnO, MgO, and alloys thereof.

12. The semiconductor laser of claim 10 wherein said cathode comprises:
a DC-biased pn GaN junction operable to generate said stream of electrons; and
a coating that provides negative electron affinity to said pn GaN junction located on a surface of said pn GaN junction that faces said wide bandgap semiconductor anode.

13. A method of making a semiconductor laser, comprising the step of:
providing a vacuum environment;
providing a stream of electrons within said vacuum environment;
providing a wide bandgap semiconductor resonant cavity to be impacted by said stream of electrons such that electron-hole pairs are generated within said wide bandgap semiconductor, and such that recombination of said electron hole pairs generates photons within said cavity, said photons having an energy generally equal to the bandgap energy of said wide bandgap semiconductor; and
providing for emission of said photons from said cavity.
